(19) United States
(12) Patent Application Publication
(10) Pub. No.: US 2009/0277679 A1
(43) Pub. Date: Nov. 12, 2009

(54) Method of manufacturing PCB and PCB manufactured by the same

(75) Inventors: Ha Yong Jung, Suwon-si (KR); Dek Gin Yang, Cheongwon-gun (KR); Cheol Ho Heo, Busan-si (KR); Chan-Yeup Chung, Daegu-si (KR); Keun Ho Kim, Daejeon-si (KR); Seoung Jae Lee, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/219,660

(22) Filed: Jul. 25, 2008

(30) Foreign Application Priority Data
May 6, 2008 (KR) 10-2008-0041696

(51) Int. Cl. H05K 3/42; H05K 1/11

(52) U.S. Cl. 174/266; 205/126

(57) ABSTRACT

Provided is a method of manufacturing a PCB, the method comprising: providing a substrate including an aluminum core; forming a via hole passing through the substrate; substituting the surface of the aluminum core with a zinc film by performing a zincate treatment on the inner surface of the via hole; substituting the zinc film with a metal film by performing substitution plating on the zinc film; forming a first plated film on the surface of the via hole, where the metal film is formed, through electroless plating; and forming a second plated film on the first plated film through electroplating.

### CROSS-REFERENCE TO RELATED APPLICATIONS

This application claims the benefit of Korean Patent Application No. 10-2008-0041696 filed with the Korea Intellectual Property Office on May 6, 2008, the disclosure of which is incorporated herein by reference.

### BACKGROUND OF THE INVENTION

1. Field of the Invention

The present invention relates to a method of manufacturing a printed circuit board (PCB) and a PCB manufactured by the same.

2. Description of the Related Art

A PCB is a component for connecting or supporting various electronic parts on a base substrate in accordance with circuit design of electrical wring lines. With the growth of home electronic appliances, communication devices, semiconductor equipments, industrial devices and so on, demand for the PCB is increasing. In particular, as electronic parts are reduced in size, PCB products are also reduced in size and weight.

Currently, the growth of the PCB market in Korea is at a standstill. However, production of some products steadily increases. These products cannot be manufactured in any other Asian countries than Korea, because a high-level technology should be required. As for the products, a build-up multilayer substrate, a flex-rigid PCB, a board for semiconductor package, an environment-friendly PBC and so on are taken as examples. Such a technology is mounted on digital information home appliances such as mobile phones, digital cameras, DVD, liquid crystal, digital video cameras, notebook PCs and so on.

One of prominent features in the digital electronic appliances is that various functions are added thereto and power consumption thereof increases. Therefore, the satisfaction and purchase criteria of consumers are determined depending on how much heat an electronic product generates. In particular, studies for reducing heat generated from mobile equipments are being actively conducted.

Conventionally, a copper clad laminate (CCL) is used as a base substrate, and a circuit pattern is formed on the CCL. Then, the plurality of CCLs are laminated so as to manufacture a multilayer PCB. However, since the conventional PCB has a material limit that copper (Cu) is used, it is difficult to enhance a heat radiation characteristic of the PCB.

Therefore, PCBs using aluminum (Al) having more excellent heat conductivity than copper have been recently developed.

In the PCB using aluminum, an insulating layer and a copper clad layer are formed on and under an aluminum core, and a via hole is formed so as to pass through the copper clad layer, the insulating layer, and the aluminum core. After that, electroless copper plating is performed to form a copper thin film on the inner surface of the via hole, and a copper film is then formed on the copper thin film through copper electroplating such that an electrical characteristic is imparted to the PCB.

In the above-described PCB using the aluminum core, however, the aluminum composing the core of the PCB has lower chemical resistance than copper. The surface of the aluminum core may corrode during the electroless copper plating.

In this case, the copper film formed in the electroless copper plating is not closely attached to the aluminum core thereunder. In the subsequent copper electroplating process, the surface of copper film comes off, and an adhesion force thereof becomes low after the plating. Therefore, the reliability of the PCB is degraded.

### SUMMARY OF THE INVENTION

An advantage of the present invention is that it provides a method of manufacturing a PCB, in which a via hole is formed in a substrate including an aluminum core, the surface of an aluminum core corresponding to the inner surface of the via hole is substituted with a zinc film, the zinc film is substituted with a nickel film, and electroless plating and electroplating are sequentially formed on the via hole. Therefore, the aluminum core can be prevented from corroding during the electroless plating, and attachment defects of a copper clad layer can be prevented from occurring, which makes it possible to enhance the reliability of products.

Another advantage of the invention is that it provides a PCB manufactured by the method of manufacturing a PCB.

Additional aspects and advantages of the present general inventive concept will be set forth in part in the description which follows and, in part, will be obvious from the description, or may be learned by practice of the general inventive concept.

According to an aspect of the invention, a method of manufacturing a PCB comprises: providing a substrate including an aluminum core; forming a via hole passing through the substrate; substituting the surface of the aluminum core with a zinc film by performing a zincate treatment on the inner surface of the via hole; substituting the zinc film with a metal film by performing substitution plating on the zinc film; forming a first plated film on the surface of the via hole, where the metal film is formed, through electroless plating; and forming a second plated film on the first plated film through electroplating.

In the substituting of the surface of the aluminum core, the side surface of the aluminum core exposed to the inner surface of the via hole may be selectively substituted with the zinc film.

In the substituting of the zinc film, the substitution plating may be performed using metal with high chemical resistance.

The metal with high chemical resistance may be selected from the group consisting of nickel (Ni), gold (Au), and silver (Ag).

In the substituting of the zinc film, the zinc film may be completely substituted with the metal film, or may be partially substituted with the metal film.

The first and second plated films may be copper films formed by copper plating.

The providing of the substrate may include: sequentially laminating an insulating layer and a copper clad layer on and under the aluminum core; and heating and pressurizing the substrate from the upper and lower sides of the substrate.

The providing of the substrate may further include performing an anodizing process on the aluminum core, before the laminating of the insulating layer and the copper layer.

The insulating layer may be formed of prepreg or resin.

The via hole may be formed by a drilling or laser process.

According to another aspect of the invention, a PCB comprises: a substrate including an aluminum core and having a via hole formed therein; a metal film that is formed by substituting a zinc film with metal, the zinc film being formed on the surface of the aluminum core corresponding to the inner surface of the via hole; a first plated film that is formed on the surface of the via hole on which the metal film is formed; and a second plated film that is formed on the first plated film.

The substituting may be performed using metal having high chemical resistance. The metal may be selected from the group consisting of Ni, Au, and Ag.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. These and/or other aspects, features, and advantages will become apparent and more readily appreciated from the following description of exemplary embodiments, taken in conjunction with the accompanying drawings of which:

FIGS. 1 to 7 are process diagrams sequentially showing a method of manufacturing a PCB according to the invention;

FIG. 8A is a SEM photograph showing a state where a zinc film is formed on an aluminum sample through a zincate treatment;

FIG. 8B is a photograph showing a result obtained by testing an adhesion force after electroless copper plating is performed on the zinc film shown in FIG. 8A;

FIG. 8C is a photograph showing a result obtained by testing an adhesion force after copper electroplating is performed;

FIG. 9A is a photograph showing a result obtained by performing an adhesion force test after the electroless copper plating and the copper electroplating are performed on an aluminum sample on which the zincate treatment and the nickel substitution plating have been performed;

FIG. 9B is an FIB (Focused Ion Beam) photograph showing a result obtained by analyzing the interface between plated films; and

FIG. 9C is an optical-microscope photograph showing a result obtained by analyzing the cross-section of the PCB including the aluminum core after the plating.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a method of manufacturing a PCB and a PCB manufactured by the same according to the present invention will be described in detail with reference to the accompanying drawings.

Referring to FIGS. 1 to 7, a method of manufacturing a PCB according to the invention will be described.

FIGS. 1 to 7 are process diagrams sequentially showing the method of manufacturing a PCB according to the invention.

First, as shown in FIG. 1, an aluminum core 10 is provided, and an insulating layer 20 and a copper clad layer 30 are sequentially laminated on and under the aluminum core 10, thereby forming a substrate 100. Then, the substrate 100 is heated and pressurized from the upper and lower sides thereof.

Before the insulating layer 20 and the copper clad layer 30 are laminated on and under the substrate, anodizing may be performed on the aluminum core 10 such that an anode oxide film (not shown) is formed on the aluminum core 10.

As the anode oxide film is formed, the aluminum core 10 has proper surface roughness such that an adhesive force thereof with respect to the insulating layer 20 can be enhanced.

The insulating layer 20 may be formed of prepreg or resin which has an adhesive property when being heated.

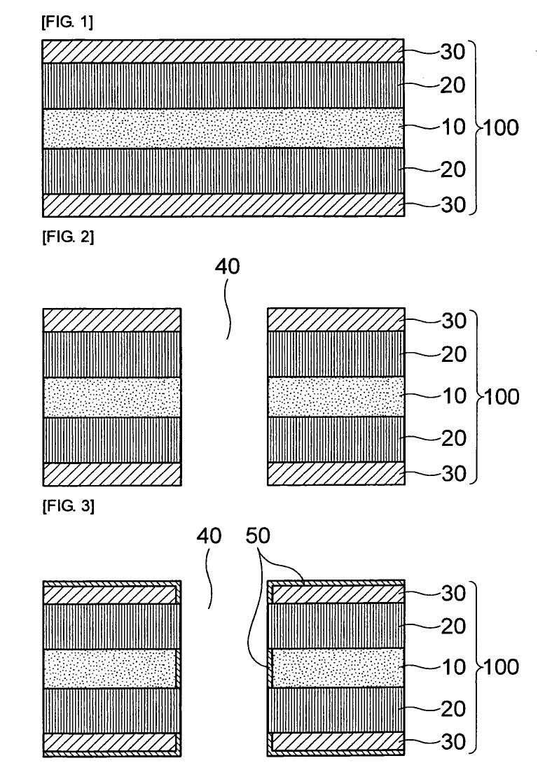

Next, as shown in FIG. 2, a via hole 40 passing through the substrate 100 is formed.

The via hole 40 may be formed through a drilling or laser process.

Then, as shown in FIG. 3, a zincate treatment is performed on the inner surface of the via hole 40 such that the surface of the aluminum core 10 is substituted with a zinc film 50 with a predetermined thickness.

As the zincate treatment is performed, the side surface of the aluminum core 10 exposed to the inner surface of the via hole 40 can be selectively substituted with a zinc film 50.

Further, during the zincate treatment, the surface of the copper clad layer 30 as well as the surface of the aluminum core 10 can be substituted with the zinc film 50..

The zincate treatment is referred to as a process in which the surface of metal such as aluminum which is apt to be oxidized in the air is substituted with zinc.

In this embodiment, as the surface of the aluminum core 10 is substituted with the zinc film 50 through the zincate treatment, the surface of the aluminum core 10 can prevented from corroding during an electroless plating or electroplating process, which will be described below.

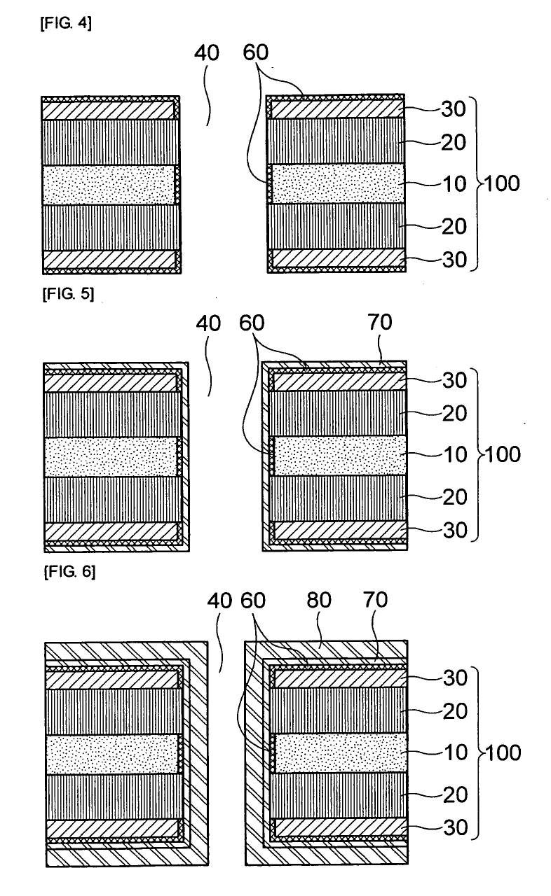

Next, as shown in FIG. 4, a substitution plating process using metal such as nickel with excellent chemical resistance is performed on the zinc film 50 such that the zinc film 50 is substituted with a nickel film 60.

FIG. 4 shows a case where the zinc film 50 is completely substituted with the nickel film 60 by the nickel substitution plating process. However, during the nickel substitution plating process of the zinc film 50, the zinc film 50 may be partially substituted with the nickel film 60 such that the zinc film 50 locally remains on the surface of the aluminum core 10 even after the nickel substitution plating process is completed.

Meanwhile, while the substitution plating process of the zinc film 50 is performed, the substation plating may be performed using another metal with excellent chemical resistance, instead of nickel. For example, gold (Au) or silver (Ag) may be used. However, it is preferable that the substitution plating process of the zinc film 50 is performed using nickel, considering a material cost.

Then, as shown in FIG. 5, a first plated film 70 is formed on the via hole 40, on which the nickel film 60 is formed, through an electroless plating process. The first plated film 70 may be a copper film formed by copper plating.

Next, as shown in FIG. 6, a second plated film 80 is formed on the first plated film 70 through an electroplating process. The second plated film 80 may be a copper film formed by copper plating, similar to the first plated film 70.

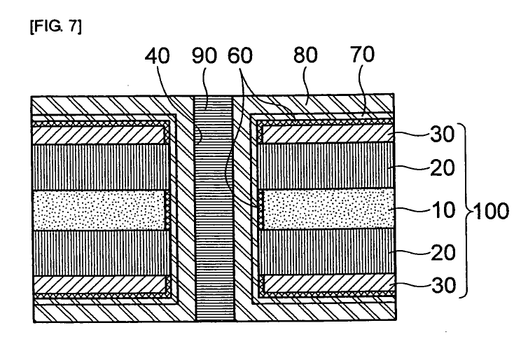

Subsequently, as shown in FIG. 7, a plugging process is performed, in which conductive materials are filled in the via hole 40.

According to this embodiment, the surface of the aluminum core 10 corresponding to the inner surface of the via hole 40 is substituted with the zinc film 50 through the zincate treatment, and the zinc film 50 is then substituted with the nickel film 60. Therefore, it is possible to prevent the aluminum core 10 from corroding during the electroless copper plating or copper electroplating process.

Therefore, the first and second plated surfaces 70 and 80 formed in the copper plating process can be closely attached to the inner surface of the via hole 40 including the aluminum core 10, which makes it possible to prevent the degradation of reliability caused by defective attachment of the plated films 70 and 80.

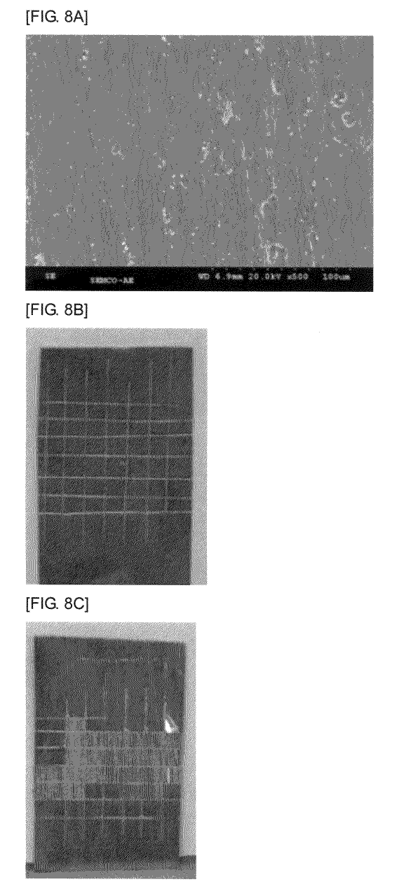

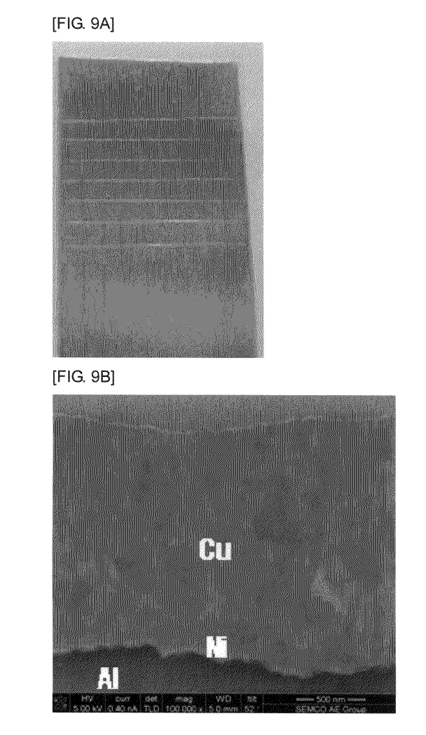

FIG. 8A is a SEM photograph showing a state where a zinc film is formed on an aluminum sample through the zincate treatment. FIG. 8B is a photograph showing a result obtained by testing an adhesion force after the electroless copper plating is performed on the zinc film shown in FIG. 8A. FIG. 8C is a photograph showing a result obtained by testing an adhesion force after the copper electroplating is performed.

As shown in FIG. 8A, it can be found that the zinc film is uniformly formed on the aluminum surface through the zincate treatment.

Next, a copper film is formed on the zinc film through the electroless copper plating, and a lattice pattern is formed on the copper film by a knife. Then, an adhesion force test is performed by attaching and detaching a tape to and from the copper film.

As a result, it can be found through FIG. 8B that the copper film is uniformly attached even after the adhesion force test.

However, when an adhesion force test is performed after the copper electroplating, the copper film is partially separated after the adhesion force test, as shown in FIG. 8.

This is because the zinc locally remains on the surface of the copper film after the electroless copper plating. As a result, during the copper electroplating, attachment defects occur due to the zinc remaining on the surface of the copper.

To solve such a problem, the zinc film 50 is formed on the surface of the aluminum core 10 through the zincate treatment, and is then substituted with the nickel film 60.

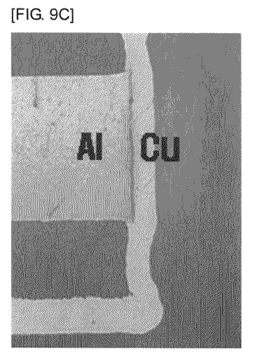

FIG. 9A is a photograph showing a result obtained by performing an adhesion force test after the electroless copper plating and the copper electroplating are performed on an aluminum sample on which the zincate treatment and the nickel substitution plating have been performed. FIG. 9B is an FIB (Focused Ion Beam) photograph showing a result obtained by analyzing the interface between the plated films. FIG. 9C is an optical-microscope photograph showing a result obtained by analyzing the cross-section of the PCB including the aluminum core after the plating.

In FIG. 9A, the zinc film formed on the aluminum sample through the zincate treatment is substituted with the nickel film, and the copper film is formed on the nickel film through the electroless copper plating and the copper electroplating. As a result of testing the adhesion force of the copper film, the copper film uniformly remains even after the adhesion force test. Therefore, it can be found that the plating has been stably performed.

FIG. 9B shows the result obtained by analyzing the interface between the plated layers by using FIB. The analysis result indicates that the interface is uniformly formed without voids or attachment defects.

FIG. 9C shows the result obtained by analyzing the cross-section of the PCB manufactured by the method of manufacturing a PCB according to the embodiment of the invention. The analysis result indicates that the plated layers are uniformly formed without attachment defects or non-plated portions.

In the above-described method of manufacturing a PCB according to the embodiment of the invention, the via hole 40 is formed in the substrate 10 including the aluminum core 10, the surface of the aluminum core 10 corresponding to the inner surface of the via hole 40 is substituted with the zinc film 50, and the zinc film 50 is substituted with the metal film such as nickel. After that, the first and second plated films 70 and 80 are formed on the surface of the via hole 40. Therefore, while the plated films 70 and 80 are formed, the corrosion of the aluminum core 10 is prevented by the metal film, which makes it possible to prevent attachment defects from occurring.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A method of manufacturing a printed circuit board (PCB), comprising:
providing a substrate including an aluminum core;
forming a via hole passing through the substrate;
substituting the surface of the aluminum core with a zinc film by performing a zincate treatment on the inner surface of the via hole;
substituting the zinc film with a metal film by performing substitution plating on the zinc film;
forming a first plated film on the surface of the via hole, where the metal film is formed, through electroless plating; and
forming a second plated film on the first plated film through electroplating.

2. The method according to claim 1, wherein in the substituting of the surface of the aluminum core, the side surface of the aluminum core exposed to the inner surface of the via hole is selectively substituted with the zinc film.

3. The method according to claim 1, wherein in the substituting of the zinc film, the substitution plating is performed using metal with high chemical resistance.

4. The method according to claim 3, wherein the metal with high chemical resistance is selected from the group consisting of nickel (Ni), gold (Au), and silver (Ag).

5. The method according to claim 1, wherein in the substituting of the zinc film, the zinc film is completely substituted with the metal film, or is partially substituted with the metal film.

6. The method according to claim 1, wherein the first and second plated films are copper films formed by copper plating.

7. The method according to claim 1, wherein the providing of the substrate includes:
sequentially laminating an insulating layer and a copper clad layer on and under the aluminum core; and
heating and pressurizing the substrate from the upper and lower sides of the substrate.

8. The method according to claim 7, wherein the providing of the substrate further includes:
performing an anodizing process on the aluminum core, before the laminating of the insulating layer and the copper layer.

9. The method according to claim 7, wherein the insulating layer is formed of prepreg or resin.

10. The method according to claim 1, wherein the via hole is formed by a drilling or laser process.

11. A PCB manufactured by the method according to claim 1.

12. A PCB comprising:
a substrate including an aluminum core and having a via hole formed therein;
a metal film that is formed by substituting a zinc film with metal, the zinc film being formed on the surface of the aluminum core corresponding to the inner surface of the via hole;
a first plated film that is formed on the surface of the via hole on which the metal film is formed; and
a second plated film that is formed on the first plated film.

13. The PCB according to claim 12, wherein the substituting is performed using metal having high chemical resistance.

14. The PCB according to claim 13, wherein the metal is selected from the group consisting of Ni, Au, and Ag.
